(19) United States
(12) Patent Application Publication
(10) Pub. No.: US 2009/0298279 A1
(43) Pub. Date: Dec. 3, 2009

(54) METHOD FOR REDUCING METAL IRREGULARITIES IN ADVANCED METALLIZATION SYSTEMS OF SEMICONDUCTOR DEVICES

(76) Inventors: Frank Feustel, Dresden (DE); Kai Frohberg, Niederau (DE); Thomas Werner, Moritzburg (DE)

Correspondence Address: WILLIAMS, MORGAN & AMERSON, 10333 RICHMOND, SUITE 1100, HOUSTON, TX, 77042, US

(21) Appl. No.: 12/394,248

(22) Filed: Feb. 27, 2009

(30) Foreign Application Priority Data
May 30, 2008 (DE) 10 2008 026 133.5

(51) Int. Cl. H01L 21/4763

(52) U.S. Cl. 438/618; 257/E21.495

(57) ABSTRACT

In a manufacturing sequence for forming metallization levels of semiconductor devices, out-gassing of volatile components after an etch process may be initiated immediately after the etch process, thereby reducing the probability of creating contaminants in other substrates and transport carriers during transport activities. Consequently, the defect rate of deposition-related irregularities in the metallization level may be reduced.

### BACKGROUND OF THE INVENTION

1. Field of the Invention

The present disclosure generally relates to the field of fabrication of integrated circuits, and, more particularly, to the manufacture of an interconnect structure by first patterning a dielectric material and subsequently depositing the metal.

2. Description of the Related Art

In a complex integrated circuit, a very large number of circuit elements, such as transistors, capacitors, resistors and the like, are formed in or on an appropriate substrate, usually in a substantially planar configuration. Due to the large number of circuit elements and the required complex layout of the integrated circuits, generally the electrical connection of the individual circuit elements may not be established within the same level on which the circuit elements are manufactured, but requires one or more additional “wiring” layers, also referred to as metallization layers. These metallization layers generally include metal lines, providing the inner-level electrical connection, and also include a plurality of inter-level connections, also referred to as vias, wherein the metal lines and vias may also be commonly referred to as interconnect structures.

Due to the continuous shrinkage of the feature sizes of circuit elements in modern integrated circuits, the number of circuit elements for a given chip area, that is, the packing density, also increases, thereby requiring an even larger increase in the number of electrical interconnections to provide the desired circuit functionality. Therefore, the number of stacked metallization layers typically increases as the number of circuit elements per chip area becomes larger. Since the fabrication of a plurality of metallization layers entails extremely challenging issues to be solved, such as providing the mechanical, thermal and electrical reliability of the many stacked metallization layers that are required, for example, for sophisticated microprocessors, semiconductor manufacturers are increasingly using a metal that allows for high current densities and reduced dimensions of the interconnections. For example, copper is a metal generally considered to be a viable candidate due to its superior characteristics in view of higher resistance against electromigration and significantly lower electrical resistivity when compared with other metals, such as aluminum, that have been used over the last decades. In spite of these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD), and also may not be effectively patterned by the usually employed anisotropic etch procedures due to its lack of forming volatile etch byproducts. In manufacturing metallization layers including copper, the so-called inlaid or damascene technique is therefore preferably used, wherein a dielectric layer is first applied and then patterned to receive trenches and vias, which are subsequently filled with copper. A further major drawback of copper is its property to readily diffuse in many low-k dielectric materials, and also in silicon and silicon dioxide, which are well-established and approved materials in fabricating integrated circuits.

It is, therefore, usually necessary to employ a so-called barrier material in combination with a copper-based metallization to substantially avoid any out-diffusion of copper into the surrounding dielectric material, as copper may readily migrate to sensitive semiconductor areas, thereby significantly changing the characteristics thereof. On the other hand, the barrier material may suppress the diffusion of reactive components, such as oxygen, fluorine and the like, into the metal region. The barrier material provided between the copper and the dielectric material should exhibit, however, in addition to the required barrier characteristics, good adhesion to the dielectric material as well as to the copper and should also have as low an electrical resistance as possible so as to not unduly compromise the electrical properties of the interconnect structure. Moreover, the barrier layer may also act as a “template” for the subsequent deposition of the copper material in view of generating a desired crystalline configuration, since a certain degree of information of the texture of the barrier layer may be transferred into the copper material to obtain a desired grain size and configuration. It turns out, however, that a single material may not readily meet the requirements imposed on a desired barrier material. Hence, a mixture of materials may be frequently used to provide the desired barrier characteristics. For instance, a bi-layer comprised of tantalum and tantalum nitride is often used as a barrier material in combination with a copper damascene metallization layer. Tantalum, which effectively blocks copper atoms from diffusing into an adjacent material even when provided in extremely thin layers, however, exhibits only a poor adhesion to a plurality of dielectric materials, such as silicon dioxide based dielectrics, so that a copper interconnection including a tantalum barrier layer may suffer from reduced mechanical stability, especially during the chemical mechanical polishing (CMP) of the metallization layer, which may be employed for removing excess copper and planarizing the surface for the provision of a further metallization layer. The reduced mechanical stability during the CMP may, however, entail severe reliability concerns in view of reduced thermal and electrical conductivity of the interconnections. On the other hand, tantalum nitride exhibits excellent adhesion to silicon dioxide based dielectrics, but has very poor adhesion to copper. Consequently, in advanced integrated circuits having a copper-based metallization, typically a barrier bi-layer of tantalum nitride/tantalum is used. Due to the demand for a low resistance of the interconnect structure in combination with the continuous reduction of the dimensions of the circuit elements and associated therewith of the metal lines and vias, the thickness of the barrier layer has to be reduced, while nevertheless providing the required barrier effect. It has been recognized that tantalum nitride provides excellent barrier characteristics even if applied with a thickness of only a few nanometers and even less. Thus, sophisticated deposition techniques have been developed for forming thin tantalum nitride layers with high conformality even in high aspect ratio openings such as the vias of advanced metallization structures, wherein the desired surface texture with respect to the further processing may also be obtained.

Since the dimensions of the trenches and vias have currently reached a width or a diameter of approximately 0.1 μm and even less with an aspect ratio of the vias of about 5 or more, the deposition of a barrier layer reliably on all surfaces of the vias and trenches and subsequent filling thereof with copper substantially without voids is a most challenging issue in the fabrication of modern integrated circuits. Currently, the formation of a copper-based metallization layer is accomplished by patterning an appropriate dielectric layer and depositing the barrier layer, for example comprised of tantalum (Ta) and/or tantalum nitride (TaN), by advanced physical vapor deposition (PVD) techniques, such as sputter deposition. Thereafter, the copper is filled in the vias and trenches, wherein electroplating has proven to be a viable process technique, since it is capable of filling the vias and trenches with a high deposition rate, compared to chemical vapor deposition (CVD) and PVD rates, in a so-called bottom-up regime, in which the openings are filled starting at the bottom in a substantially void-free manner. Generally, when electroplating a metal, an external electric field is applied between the surface to be plated and the plating solution. Since substrates for semiconductor production may be contacted at restricted areas, usually at the perimeter of the substrate, a conductive layer covering the substrate and the surfaces that are to receive a metal has to be provided. Although the barrier layer previously deposited over the patterned dielectric may act as a current distribution layer, it turns out, however, that, in view of crystallinity, uniformity and adhesion characteristics, preferably a so-called seed layer is to be used in the subsequent electroplating process to obtain copper trenches and vias having the required electrical and mechanical properties. The seed layer, usually comprised of copper, is typically applied by sputter deposition using substantially the same process tools as are employed for the deposition of the barrier layer, wherein these deposition techniques may provide the desired texture of the seed layer in combination with the previously deposited barrier material, thereby creating appropriate conditions for the subsequent filling in of the bulk metal.

For dimensions of 0.1 μm and less of vias in advanced semiconductor devices, the sputter deposition of extremely thin metal layers having a high degree of conformity, as required for the barrier layer and the seed layer, may represent critical process steps, since the step coverage characteristics of the above-described advanced sputter techniques may depend on the overall surface characteristics of the dielectric material, which in turn has to be patterned on the basis of highly sophisticated lithography and etch techniques. Even if other process techniques may be used in forming appropriate barrier materials, for instance on the basis of highly conformal deposition processes, such as atomic layer deposition (ALD), which is a well-controllable self-limiting CVD-like process, superior surface characteristics may also have to be provided prior to the deposition of the barrier material and a seed material, if required. For example, deposition-related irregularities during the formation of the barrier material and the seed material may cause the creation of voids in the barrier material and possibly in the subsequently deposited copper metal, thereby deteriorating the electrical performance of the resulting interconnect structure while also contributing to a reduced degree of reliability since premature failure of interconnect structures may be observed due to a reduced resistance against electromigration caused by voids and other interface irregularities in the barrier material and/or the copper material. For this reason, great efforts are made in appropriately preparing the surface of the patterned dielectric material prior to the deposition of the barrier material and the seed material, which may include wet chemical and plasma-assisted cleaning processes. For example, during the sophisticated etch techniques for forming vias and trenches in the dielectric material, a plurality of surface contaminations may be generated, for instance in the form of organic etch byproducts and the like, which may require sophisticated cleaning recipes, for instance on the basis of wet chemical techniques using appropriate chemistries, such as diluted hydrofluoric acid, APM (a mixture of ammonia and hydrogen peroxide) and the like. Other possible sources of contamination represent underlying metal regions which may be exposed by the preceding patterning sequence so that, increasingly, metal atoms may be liberated from the underlying region and may be redistributed at lower sidewall portions of critical vias, thereby forming respective agglomerated metal clusters, which may also result in deposition-related irregularities during the further processing of the semiconductor device. Additionally, the dielectric material itself may contain a plurality of volatile components which may increasingly diffuse out of the material, for instance via the corresponding opening formed by the previous etch process. These volatile components may themselves, or in combination with other components such as exposed metal surfaces and the like, result in inferior process conditions during the subsequent deposition of the barrier and seed material and possibly also in a subsequent wet chemical deposition process for forming the copper material. Consequently, in addition to complex cleaning processes which may require specific cleaning tools, the semiconductor devices may be exposed to an appropriate ambient for promoting the out-gassing of volatile components immediately prior to the deposition of the barrier material in order to enhance the overall process conditions and suppress the creation of deposition-related irregularities. When reducing features sizes, such as the gate length of transistor elements, the respective metal features in the metallization level of the semiconductor devices also have to be reduced, wherein, however, increasingly, interconnect failures may be observed due to the creation of voids at critical interfaces, for instance at the interface between a barrier material and a highly conductive metal, such as copper, although sophisticated cleaning and de-gas processes may be applied prior to the deposition of the barrier and seed materials.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to techniques for forming interconnect structures in metallization levels of advanced semiconductor devices wherein the probability of creating voids and other irregularities in the interconnect structures, in particular at interfaces, may be reduced by taking into consideration transport-related contamination, which are assumed to be a reason for increased void generation during the entire process sequence. Without intending to restrict the present application to the following explanation, it is assumed that a certain degree of out-gassing of volatile contaminants, in particular during the transport activity between respective process tools in a common transport carrier, such as a front opening unified pod (FOUP), may significantly contribute to inferior process conditions during the deposition of the barrier material and the seed material and also afterwards when the barrier material and/or the seed material may come into contact with other substrates and the transport carrier, which may have been contaminated during the preceding transport activities. Consequently, by reducing the rate of out-gassing of volatile contaminants after the patterning of the dielectric material of the metallization level, superior conditions during the subsequent manufacturing sequence may be established, thereby reducing the probability of creating voids and other deposition-related irregularities.

One illustrative method disclosed herein comprises supplying a group of substrates to a first process tool in a common transport carrier, wherein each of the substrates comprises a dielectric material of a metallization layer of a semiconductor device. The method further comprises forming an opening in the dielectric material using the process tool and exposing the group of substrates to a de-gas ambient for promoting out-gassing of volatile components, wherein the de-gassed ambient is established in the first process tool. Furthermore, after exposure to the de-gas ambient, the group of substrates is transported to a second process tool using the common transport carrier. Finally, the method comprises treating the group of substrates in the second process tool to prepare exposed surface areas of the dielectric material for forming a conductive material thereon.

A further illustrative method disclosed herein comprises supplying a group of substrates to a first process tool in a first transport carrier, wherein each of the substrates comprises a dielectric material of a metallization layer of a semiconductor device, and wherein the dielectric material includes openings therein for forming metal features. The method additionally comprises performing a cleaning process in the first process tool and exposing the group of substrates to a de-gas ambient for promoting out-gassing of volatile components, wherein the de-gas ambient is established in the first process tool. Furthermore, the method comprises transporting the group of substrates to a second process tool using a second transport carrier that differs from the first transport carrier. Additionally, a conductive material is formed on exposed surface areas of the dielectric material in the second process tool.

A still further illustrative method disclosed herein comprises processing a substrate in a first process tool so as to form an opening in a dielectric layer of the semiconductor device that is formed above the substrate. The method further comprises reducing a rate of out-gassing of the dielectric layer at least during a transport activity for transporting the substrate to a second process tool in a transport carrier. Finally, the method comprises performing a process sequence for depositing a metal in the opening by using at least the second process tool.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a process flow for forming an interconnect structure in a metallization level of semiconductor devices including a plurality of process tools and related transport activities, wherein it is assumed, according to the principles disclosed herein, that contamination of substrates and/or transport carriers may result in inferior process conditions during the overall process sequence;

FIG. 1b schematically illustrates a mechanism for back side and transport carrier contamination by out-gassing of volatile contaminants during transport activities in conventional strategies;

FIG. 2a schematically illustrates a process flow for forming an interconnect structure on the basis of superior process conditions due to a reduced probability of creating deposition-related irregularities, such as voids and the like, according to illustrative embodiments;

FIG. 2b schematically illustrates a further process flow in which the probability of contaminating substrates and transport carriers may be reduced, wherein a de-gas ambient may be established in situ with a cleaning tool, according to further illustrative embodiments;

FIG. 2c schematically illustrates a process flow in which out-gassing may be caused prior to or after a cleaning process which may also include the cleaning of the substrate back sides, according to further illustrative embodiments; and

FIG. 2d schematically illustrates a process sequence in which the probability of undesired out-gassing of volatile components may be reduced at least during the transport activities by establishing an appropriate atmosphere within the transport carriers, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developer' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

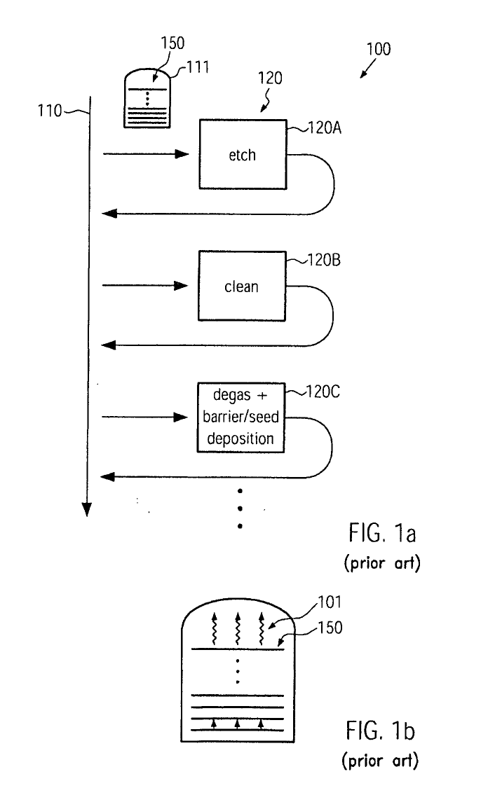

Generally, the subject matter disclosed herein provides techniques in which superior process conditions may be established for forming sophisticated interconnect structures in metallization levels of semiconductor devices by taking into consideration transport-related contamination. As will be described later on with reference to FIGS. 1a-1b, it is believed that the liberation of volatile components after the etch process may contribute to a contamination of transport carriers and possibly back sides of substrates, which in turn may cause inferior deposition conditions when forming a barrier material, a seed layer and a highly conductive metal such as copper. As previously explained, a sequence of highly complex individual process steps, which may be performed in dedicated process tools, may be required to obtain interconnect structures of critical dimensions that may be approximately 0.1 μm and even less, wherein, however, due to the mutual complex dependencies of the various processes and materials, even subtle defects may significantly influence the overall process result, in particular when critical device dimensions are further scaled. By identifying one possible source for creating irregularities, such as voids, a significant enhancement of performance and reliability of the metallization systems may be accomplished by appropriately modifying the overall process sequence and/or introducing additional measures for reducing the probability of creating transport-related contaminations. In some illustrative aspects disclosed herein, the degree of contamination by out-gassing components may be reduced by actively performing a de-gas process immediately after patterning the dielectric material of the metallization layer under consideration prior to performing a transport activity in a common transport carrier. Consequently, by performing an “in situ” de-gas process in an etch tool, the contamination of other substrates and of the transport carrier may be reduced, thereby also reducing the probability of creating any defects during the further process sequence. In other illustrative aspects disclosed herein, the de-gas process may be combined with the cleaning of the substrates in combination with providing a substantially non-contaminated transport carrier after the cleaning sequence including the de-gas process, thereby providing superior surface conditions of the substrates, which may then be supplied to other process tools on the basis of a significantly reduced degree of contamination. In still other illustrative aspects disclosed herein, the ambient in the transport carrier may be modified to reduce the rate of out-gassing, for instance by applying an appropriate ambient with over pressure, thereby also contributing to a reduced probability of creating defects during the further processing, wherein any of the above-described techniques may be combined to further enhance overall process conditions.

With reference to FIGS. 1a-1b, a conventional process strategy will now be described in more detail in which a possible source of surface contaminations may be identified according to the principles disclosed herein.

FIG. 1a schematically illustrates a portion of a manufacturing environment 100 which may comprise a transport system 110, which may represent an automatic transport system or a semiautomatic transport system, as is typically provided in complex manufacturing systems for fabricating semiconductor devices. For example, the transport system 110 may comprise an appropriately designed rail system in combination with respective transport vehicles that may be controlled by a supervising control system (not shown) to exchange transport carriers 111 with process tools 120 within the environment 100 according to a specified overall schedule. That is, by means of the transport system 110, substrates 150 may be delivered to respective process tools 120 and may be picked up, wherein the corresponding transport activities may typically involve a plurality of substrates, such as a group, which may also be referred to as a lot, contained in a respective one of the transport carriers 111. For example, according to conventional transport strategies, a specific group of substrates 150 may be associated with a corresponding transport carrier 111 and may be passed through a sequence of processes using the process tools 120. Consequently, the group of substrates 150 may be supplied to a specific process tool 120 and after processing therein may again be stored in the same transport carrier 111 to be picked up by the transport system 110 and supplied to the next process tool. For example, the plurality of process tools 120 may comprise an etch tool 120A, a clean tool 120B and a process tool 120C designed to establish a de-gas ambient and deposit a barrier or seed material in accordance with a specified deposition technique, such as sputter deposition and the like.

During a typical sequence for forming a metallization level of a semiconductor device, the group of substrates 150 may be supplied to the etch tool 120A, for instance, after providing an appropriate etch mask on the basis of lithography techniques. After performing the etch process, the substrates 150 may be supplied to the cleaning tool 120B, which may be operated on the basis of wet chemical etch recipes, plasma-assisted etch recipes and the like, depending on the overall process strategy. Thereafter, the substrates 150 may be supplied via the transport carrier 111 to the process tool 120C, in which an appropriate process chamber may be provided in which a de-gas ambient may be established, that is, an ambient appropriate for raising the surface temperature of the substrates 150 and promoting the out-gassing of volatile components, for instance by establishing a certain low pressure ambient and the like. Thereafter, the substrates 150 may be supplied into a further process module by tool-internal transport systems, such as robot handlers, without requiring the use of the transport carrier 111. After depositing an appropriate conductive barrier material and a seed layer, the substrates 150 may be received in the transport carrier 111 and may be supplied to an electro-chemical deposition tool in which a metal may be deposited on the seed layer in accordance with well-established process techniques. During the various transport activities in the environment 100, respective volatile components, such as reactive components in the form of oxygen, fluorine and the like, as well as organic etch byproducts, metal-containing species and the like, may diffuse out of the patterned dielectric material and may re-deposit on other substrates and also on surface areas of the transport carrier 111.

FIG. 1b schematically illustrates the transport carrier 111 including the plurality of substrates 150 during a transport activity after processing the substrates 150 in the etch tool 120A. As schematically illustrated, volatile components 101 may be liberated into the atmosphere within the transport carrier 111 and may deposit on adjacent surface areas. For example, the uppermost substrate may be positioned in the vicinity of a surface area of the transport carrier 111, thereby contaminating the respective surface area. On the other hand, any substrates 150 positioned in intermediate locations within the transport carrier 111 may also emit volatile components, which may preferably deposit on back sides of adjacent substrates. Consequently, during the various transport activities from the tool 120A to the tool 120B and from the tool 120B to the tool 120C, an increasing degree of contamination may be created at the respective back sides of the substrates 150 and at surface areas of the transport carrier 111. Depending on the process strategy, the de-gas ambient established in the process tool 120C may result in a significant reduction of volatile components at the front side of the substrates 150, while the back side of the substrates may be cleared to a lesser amount, for example in view of substrate handling during the de-gas process and the like. Consequently, during respective substrate handling activities within the process tool 120C for positioning the substrates 150 within the corresponding deposition modules, an increased degree of contamination may occur, thereby contributing to an increased defect rate. Moreover, after the deposition of the seed material, the substrates 150 may be re-transferred to the transport carrier 111, which may contain the previously accumulated surface contaminations, possibly in combination with additional contaminants attached to the back sides of the substrates, thereby contributing to an increased degree of contamination of the seed layer, which may result in deposition-related irregularities during the subsequent electrochemical deposition process.

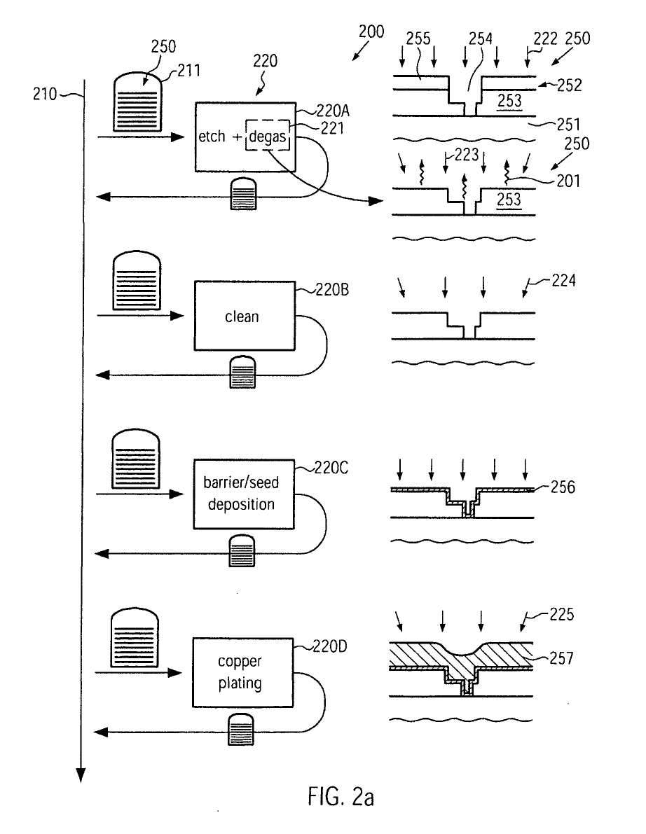

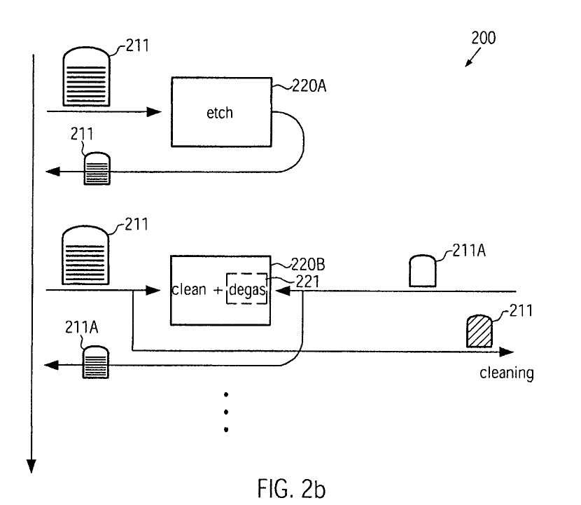

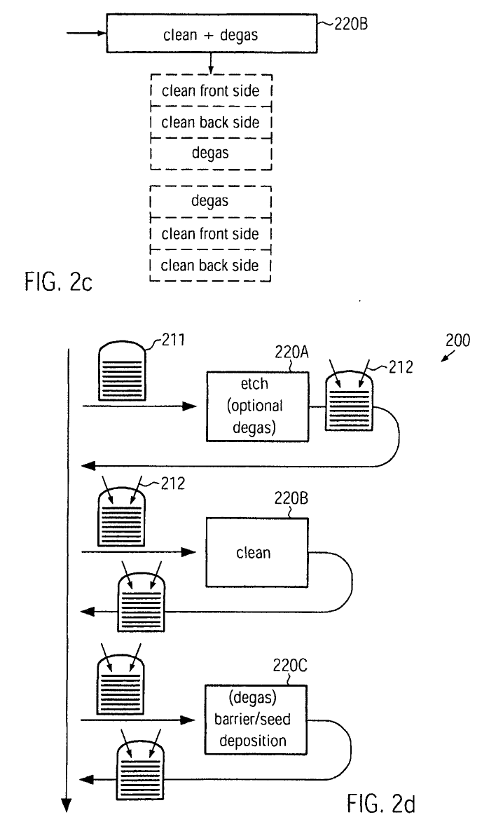

With reference to FIGS. 2a-2d, illustrative embodiments will now be described in more detail in which the teaching discussed above with reference to FIGS. 1a-1b may be taken into consideration to reduce the probability of creating defects during a process sequence for forming interconnect structures in sophisticated semiconductor devices.

FIG. 2a schematically illustrates a manufacturing environment 200 comprising a transport system 210 and a plurality of process tools 220. With respect to the transport system 210 and at least some of the process tools 220, the same criteria apply as previously explained with reference to the manufacturing environment 100. Thus, the manufacturing environment 200, as shown in FIG. 2a, may be appropriately configured to process substrates 250 in and above which corresponding semiconductor devices may be provided, and may receive interconnect structures as are typically required for metallization levels of advanced semiconductor devices. The substrates 250 may be handled by the transport system 210 on the basis of appropriate transport carriers 211, such as FOUPs, as previously explained. Consequently, the substrates 250 may be passed through the plurality of process tools 220 according to a specified schedule and process strategy, wherein, however, contrary to the manufacturing environment 100 shown in FIG. 1a, transport-related contamination of transport carriers and/or other substrates may be taken into consideration. In the embodiment shown, the manufacturing environment 200 may comprise an etch tool 220A, in which one or more etch modules may be provided for patterning a dielectric material and wherein the substrates, individually or commonly, may be handled by tool-internal substrate handling systems, such as robot handlers, to provide the substrates 250 to a further process module 221 that is configured to establish a de-gas ambient for promoting the out-gassing of volatile components, as previously explained. Consequently, the substrates 250 may be processed in the process tool 220A such that first an etch process may be performed and subsequently the substrates 250 may be treated in order to promote the out-gassing of volatile components without requiring an intermediate transport activity on the basis of the transport carrier 211.

At the right-hand side of FIG. 2a, the process steps performed in the process tool 220A are illustrated in an exemplary manner for one of the substrates 250. As illustrated, the substrate 250 may comprise a base material 251, which may represent any appropriate carrier material, such as a silicon material and the like, in and above which circuit elements may be provided, for instance in the form of transistors, capacitors and the like, as may be required by the design rules of the semiconductor device under consideration. For example, in the base material 251, an appropriate semiconductor material may be provided in and above which transistor elements may be formed that have a gate length of approximately 50 nm and less, when advanced circuitry is considered, formed on the basis of field effect transistors. Furthermore, a metallization layer 252 may be formed above the base material 251, which in the early manufacturing stage of the metallization layer 252 may comprise an appropriate dielectric material 253, for instance in the form of a low-k dielectric material, silicon dioxide, silicon nitride or any other appropriate material. Furthermore, in this manufacturing stage, an etch mask 255 may be provided above the dielectric material 253 and may have respective openings therein according to design rules.

The substrate 250 as shown in FIG. 2a in the process tool 220A may be formed in accordance with well-established process techniques. In a first process step in the tool 220A, an etch ambient 222 may be established for which well-established process recipes may be used in order to anisotropically etch the dielectric material 253 on the basis of the etch mask 255, thereby forming an opening 254, for instance in the form of a trench, possibly in combination with a via opening, as may be required for providing a respective interconnect structure in the metallization level 252. After the etch process 222, the substrate 250 may be positioned in the process module 221, in which a de-gas ambient 223 may be established, for instance by heating the substrate 250 and establishing an appropriate gaseous ambient, for instance in an inert gas ambient with reduced pressure and the like. Consequently, volatile components 201 may be released into the ambient 223 and may be removed. After exposing the substrates 250 to the de-gas ambient 223, the substrates 250 may be re-positioned in the transport carrier 211 and may be picked up by the automatic transport system 210, wherein, contrary to the conventional strategy, the rate of out-gassing of the volatile components 201 during the transport activities within the transport carrier 211 may be reduced.

Thereafter, the substrates 250 may be supplied to a cleaning tool 220B, in which an appropriate cleaning ambient 224 may be established, as is shown at the right-hand side of FIG. 2a. The cleaning ambient may be established on the basis of advanced wet chemical recipes, for instance on the basis of hydrofluoric acid (HF), APM and the like. In other cases, plasma-assisted cleaning processes may be used, depending on the overall process strategy. After treating the substrates 250 in the tool 220B on the basis of the ambient 224, the substrates 250 may be positioned in the transport carrier 211 and may be supplied to a further process tool 220C, wherein also during this transport activity a reduced rate of out-gassing of the volatile components 201 may be accomplished. In the process tool 220C, a conductive material 256 may be deposited, for instance in the form of a barrier material, possibly in combination with a seed material, depending on the overall process strategy. For example, tantalum and tantalum nitride may be used as efficient barrier materials, as previously explained, while an efficient seed material may be provided in the form of copper. It should be appreciated that, in other process strategies, copper may be directly deposited on a barrier material, such as tantalum-based materials, ruthenium-based materials and the like, without requiring a seed material. However, also in this case, superior surface conditions of the barrier material may be required so that significant contamination of the volatile components 201 during previous processes and transport activities is to be reduced. As previously indicated, even if a sensitive copper material may be provided as a seed layer in the material 256, contamination thereof may be reduced due to the reduced probability of releasing the volatile components 201. After the deposition of the conductive material 256, the substrates 250 may be supplied to a further process tool 220D, which may represent an electrochemical deposition tool, such as a plating reactor and the like, in which a layer of conductive metal 257, such as copper, may be deposited during a process 225, as is illustrated at the right-hand side of FIG. 2a. Thereafter, the further processing may be continued by removing any excess material and planarizing the surface topography of the metallization level 252, for instance on the basis of chemical mechanical polishing (CMP) and the like.

Consequently, the opening 254 of the substrates 250 may be filled with a conductive material, such as a barrier material, a seed material and the material of the layer 257 with a reduced probability of creating deposition-related irregularities, such as voids, thereby enhancing electrical performance of the corresponding metal features of the metal level 252 and also enhancing reliability with respect to live time, since electromigration-induced interconnect failures may be reduced.

FIG. 2b schematically illustrates the manufacturing environment 200 according to further illustrative embodiments in which, additionally or alternatively, the de-gas module 221 may be provided within the process tool 220B in order to enable an in situ cleaning and de-gassing process. In the embodiment shown, the etch tool 220A may be configured in a similar manner as is also the case in the conventional manufacturing environment 100, as shown in FIG. 1a. Consequently, the substrates 250 may be processed in the tool 220A on the basis of well-established etch recipes and may subsequently be transported by means of the carrier 211 to the tool 220B, wherein, however, as previously indicated, a certain degree of contamination of the carrier 211 and possibly other substrates may occur. In the process tool 220B, in some illustrative embodiments, the substrates 250 may first be exposed to the de-gas ambient 223 in order to significantly reduce the amount of volatile components, and subsequently the substrates 250 may be subjected to the cleaning process 224 (see FIG. 2a). In other illustrative embodiments, the cleaning process 224 may be performed prior to the de-gas process, while, in other cases, the cleaning ambient 224 and the de-gas ambient 223 may be established within the same process chamber, depending on the characteristics of the cleaning ambient. Moreover, the scheduling of transport activities at the process tool 220B may be appropriately controlled so as to supply a substantially decontaminated substrate carrier 211A to the process tool 220B so as to receive the substrates 250 that are currently being processed in the tool 220B. Additionally, the substrate carrier 211 may be removed from the tool 220B after supplying the last substrate 250 contained therein and may be subjected to a cleaning process at any appropriate process tool within the environment 200. Consequently, after the process 220B, the substrates 250 may be transported by the carrier 211A of reduced contamination, while at the same time reducing the probability of creating further contaminants in the carrier 211A due to the previously performed de-gas process. Thus, the substrates 250 may be supplied to the further process tools 220C, 220D (see FIG. 2a) so as to perform the further processing with a reduced risk of generating deposition-related irregularities. Incorporating the de-gas module 221 into the tool 220B may provide an efficient overall process strategy since, depending on the cleaning recipe used, the interaction of the cleaning ambient with the exposed surface portions of the substrates 250 may also result in an interaction with sources of the out-gassing of the components so that, after completion of the processing in the tool 220B, in general, a very low degree of contamination of the transport carrier 211A may be achieved.

FIG. 2c schematically illustrates further process flow variations according to further illustrative embodiments. As shown in one illustrative embodiment, the processing in the tool 220B may comprise a cleaning process, such as the process 224 (FIG. 2a) for removing etch-related byproducts from the front side of the substrate 250, and also contaminants may be removed from the back side of the substrates 250, thereby further reducing the probability of creating contamination during the further processing of the substrates 250. The cleaning of the back side of the substrates 250 may be accomplished on the basis of dedicated process modules, which are per se known in the art. Thereafter, the de-gassed ambient 223 (FIG. 2a) may be established, as previously described.

FIG. 2c further illustrates an embodiment in which the de-gassed ambient 223 may be established prior to performing a cleaning sequence including the cleaning of the front side and the back side of the substrates 250. In this case, a possible contamination of the substrates 250 caused by the volatile components 201 released during the de-gas ambient 223 may be efficiently removed during the cleaning process in the tool 220B, and thereafter the substrates 250 may be transported in the carrier 211A (FIG. 2b), as previously described.

It should be appreciated that the back side cleaning process may also be performed in the process flow as described with reference to FIG. 2a so that any possible contamination caused by the de-gas ambient 223 established in the tool 220A may also be efficiently removed. Furthermore, a further de-gas ambient may be established at any appropriate stage of the manufacturing sequence in the environment 200 in addition to the ambient 223. For example, a corresponding de-gas process may be performed prior to the deposition of the conductive material 256 in the process tool 220C (FIG. 2a), as may also be practiced in the conventional strategy as shown in FIG. 1a.

With reference to FIG. 2d, further illustrative embodiments will be described in which the rate of out-gassing of the volatile components 201 may be reduced, at least during each transport activity.

FIG. 2d schematically illustrates the environment 200, wherein the substrates 250 may be supplied to the tool 220A by using the transport carrier 211. In the tool 220A, the etch process may be performed, as previously described, possibly in combination with a de-gas process, if desired. Thereafter, the substrates 250 may be positioned in the carrier 211, in which additionally an ambient 212 may be established to reduce out-gassing of volatile components. For example, an inert gas ambient may be established, for instance with a certain amount of over pressure compared to conventional strategies in order to hinder the release and the re-deposition of any volatile components. Based on the ambient 212, the substrates 250 may be supplied to the tool 220B and may, after processing therein, be transported to the tool 220C on the basis of the ambient 212. Similarly, the substrates 250 may be processed in the tool 220C, for instance by performing a de-gas process, and thereafter the substrates 250 may be supplied to further process tools, such as the electrochemical deposition tool 220D (FIG. 2a) on the basis of the ambient 212. Consequently, the probability of contaminating other substrates and/or surface areas of the transport carrier 211 may be reduced by establishing the ambient 212 during each transport activity in the environment 200. Moreover, the transport activity with the ambient 212 may be combined with any of the process strategies as described with reference to FIGS. 2a-2c so as to even further enhance the process conditions during the deposition of the conductive material 256 and the layer 257 (FIG. 2a).

As a result, the present disclosure provides techniques for reducing the probability of creating voids or other irregularities during the formation of copper-based interconnect structures in that out-gassing during the various processes and the related transport activities is taken into consideration. Consequently, well-established etch recipes and other process techniques may be used, thereby providing a high degree of compatibility with well-established recipes, while at the same time enhanced performance and reliability of the resulting interconnect structures may be obtained. In some illustrative embodiments, this may be accomplished by incorporating a de-gas module into the etch tool, thereby providing an in situ reduction of out-gassing of volatile components. In other illustrative embodiments, the scheduling of the transport system may be appropriately controlled so as to exchange the transport carrier at least once prior to the critical deposition processes in order to reduce contamination of critical surface areas. For this purpose, prior to the deposition of the barrier material or prior to the deposition of the copper material, the transport carrier may be replaced by a substantially non-contaminated carrier, for instance by allowing the corresponding process tools to receive the processed substrates by a different transport carrier, thereby reducing the overall probability of contamination caused by volatile components adhering to surface areas of the transport carrier. In other illustrative embodiments, the performing of a de-gas process may be combined with a provision of a substantially non-contaminated transport carrier, for instance after completing the processing in a cleaning process tool, which may also contain a respective module for establishing a de-gas ambient, so that enhanced overall surface conditions may be provided prior to the deposition of a barrier material. In still other illustrative embodiments, additionally or alternatively, the probability of out-gassing may be reduced during the transport activities, for instance, by establishing appropriate atmospheric conditions within the transport carrier. The principles disclosed herein may be advantageously applied to other etch processes that may have to be performed during the manufacturing of metallization levels. For instance, by incorporating a respective module or establishing a de-gas ambient into an etch tool, any etch process to be performed during the fabrication of the metallization level may be combined with a de-gas process, substantially adding to additional process complexity.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
supplying a group of substrates to a first process tool in a common transport carrier, each of said substrates comprising a dielectric material of a metallization layer of a semiconductor device;
forming an opening in said dielectric material using said process tool;
exposing said group of substrates to a de-gas ambient for promoting out-gassing of volatile components, said de-gas ambient being established in said first process tool;
after exposure to said de-gas ambient, transporting said group of substrates to a second process tool using said common transport carrier; and
treating said group of substrates in said second process tool so as to prepare exposed surface areas of said dielectric material for forming a conductive material thereon.

2. The method of claim 1, wherein treating said group of substrates comprises performing a wet chemical cleaning process.

3. The method of claim 2, wherein performing said wet chemical cleaning process comprises cleaning a back side of said substrates.

4. The method of claim 2, further comprising transporting said group of substrates to a third process tool using said common transport carrier and forming a conductive barrier material on said exposed surface areas in said third process tool.

5. The method of claim 4, further comprising exposing said group of substrates to a further de-gas ambient prior to forming said conductive barrier material.

6. The method of claim 4, further comprising forming a seed layer on said barrier material in said third process tool.

7. The method of claim 5, further comprising transporting said group of substrates to an electrochemical deposition tool by using said common transport carrier.

8. The method of claim 2, wherein treating said group of substrates in said second process tool comprises forming a conductive barrier material on said exposed surface areas.

9. The method of claim 8, further comprising exposing said group of substrates to a further de-gas ambient in said second process tool prior to forming said conductive barrier material.

10. A method, comprising:
supplying a group of substrates to a first process tool in a first transport carrier, each of said substrates comprising a dielectric material of a metallization layer of a semiconductor device, said dielectric material including openings therein for forming metal features;
performing a cleaning process in said first process tool;
exposing said group of substrates to a de-gas ambient for promoting out-gassing of volatile components, said de-gas ambient being established in said first process tool;
transporting said group of substrates to a second process tool using a second transport carrier other than said first transport carrier; and
forming a conductive material on exposed surface areas of said dielectric material in said second process tool.

11. The method of claim 10, wherein performing said cleaning process comprises establishing a wet chemical cleaning ambient.

12. The method of claim 10, wherein performing said cleaning process comprises cleaning a front side and a back side of each of said substrates.

13. The method of claim 10, wherein said cleaning process is performed prior to exposing said substrates to said de-gas ambient.

14. The method of claim 10, wherein said cleaning process is performed after exposing said substrates to said de-gas ambient.

15. The method of claim 10, wherein forming said conductive material on exposed surface areas comprises forming a conductive barrier material.

16. The method of claim 15, further comprising forming a seed material on said conductive barrier material using said second process tool.

17. The method of claim 15, further comprising transporting said group of substrates to a third process tool by using one of said second transport carrier and a third transport carrier having a decontaminated interior, and depositing a metal above said conductive barrier material using said third process tool.

18. A method, comprising:
processing a substrate in a first process tool so as to form an opening in a dielectric layer of a semiconductor device formed above said substrate;
reducing a rate of out-gassing of said dielectric layer at least during a transport activity for transporting said substrate to a second process tool in a transport carrier; and
performing a process sequence for depositing a metal in said opening by using at least said second process tool.

19. The method of claim 18, wherein reducing a rate of out-gassing comprises establishing a de-gas ambient in said first process tool prior to performing said transport activity.

20. The method of claim 18, wherein reducing a rate of out-gassing comprises providing over pressure in said transport carrier when performing said transport activity.

21. The method of claim 20, wherein performing said process sequence comprises performing a cleaning treatment in said second process tool and depositing a conductive barrier material in a third process tool.

22. The method of claim 18, further comprising cleaning said dielectric layer after forming said opening and prior to reducing said out-gassing rate at least during said transport activity to transport said substrate to said second process tool.
